(19) United States
(12) Patent Application Publication
(10) Pub. No.: US 2006/0252191 A1
(43) Pub. Date: Nov. 9, 2006

(54) Methodology for deposition of doped SEG for raised source/drain regions

(75) Inventors: Thorsten Kammler, Ottendorf-Okrilla (DE); Helmut Bierstedt, Dresden (DE); Scott D. Luning, Poughkeepsie, NY (US)

Correspondence Address: LARSON NEWMAN ABEL POLANSKY & WHITE, LLP, 5914 WEST COURTYARD DRIVE, SUITE 265, AUSTIN, TX, 78730, US

(73) Assignee: Advanced Micro Devices, Inc., Sunnyvale, CA (US)

(21) Appl. No.: 11/120,857

(22) Filed: May 3, 2005

(51) Int. Cl. H01L 21/8234; H01L 21/336; H01L 21/8238

(52) U.S. Cl. 438/197; 438/301; 438/300; 438/199

(57) ABSTRACT

A first gate structure and a second gate structure are formed overlying a semiconductor substrate. A first protective layer is formed overlying the first gate structure and an associate source drain region. A first epitaxial layer is formed overlying the second source drain prior to removal of the first protective layer.

### CROSS-REFERENCE TO RELATED APPLICATIONS

Related subject matter is found in a co-pending U.S. Patent Application, having application Ser. No. 10/791,346 (Attorney Docket Number 1458-H1946), filed Mar. 2, 2004, entitled “CONTAMINATION REMOVAL PROCESSES DURING SEMICONDUCTOR MANUFACTURING,” which is hereby incorporated herein by reference in its entirety. Related subject matter is found in a co-pending U.S. patent application, having application Ser. No. 10/969,769 (Attorney Docket Number 1458-H1962), filed Oct. 20, 2004, entitled “METHODS FOR POST OFFSET SPACER CLEAN FOR IMPROVED SELECTIVE EPITAXY SILICON GROWTH,” which is hereby incorporated herein by reference in its entirety. Related subject matter is found in a co-pending U.S. patent application, having application Ser. No. 11/076,277 (Attorney Docket Number 1458-H1952), filed Mar. 9, 2005, entitled “SEMICONDUCTOR DEVICE AND METHOD OF FORMING,” which is hereby incorporated herein by reference in its entirety.

### BACKGROUND

1. Field of the Disclosure

The present disclosure relates generally to a semiconductor manufacturing process, and more particularly to a method of epitaxial formation.

2. Description of the Related Art

Thin-film fully-depleted (FD) Silicon-on-Insulator (SOI) has shown to be an attractive candidate for deep sub-micron CMOS low-power, high-speed applications. For FD SOI CMOS, scaling also includes reducing the thickness of the thin silicon film of the SOI substrate. During device fabrication, however, the silicidation of ultra thin-films (<50 nm) may consume the entire silicon film in the S/D areas. This results in a high source/drain (S/D) contact resistance, or possibly the formation of a void between the extension and S/D area, which will result in device failure.

In order to avoid these detrimental effects, extra silicon should be provided in the S/D areas by using Selective Epitaxial Growth (SEG) of silicon. However, since the epitaxial growth includes a high-temperature pre-bake at 900 degrees C., this process is not very attractive for sub-100 nm devices unless the device fabrication scheme is altered.

Therefore a method which overcomes these problems would be useful.

### BRIEF DESCRIPTION OF THE DRAWINGS

The present disclosure may be better understood, and its numerous features and advantages made apparent to those skilled in the art by referencing the accompanying drawings. It will be appreciated that the various features in the accompanying drawings are not necessarily drawn to scale relative to other features.

FIGS. 1 through 8 illustrate, in cross-section, semiconductor device manufacturing process steps according to at least one embodiment of the present disclosure;

FIG. 9 illustrates, in cross-section, a portion of a semiconductor device manufactured according to an embodiment of the present disclosure; and

FIG. 10 is a flow diagram illustrating a method for determining a desired thickness of a source-drain region for a semiconductor device according to an embodiment of the present disclosure.

The use of the same reference symbols in different drawings indicates similar or identical items.

### DESCRIPTION OF THE PREFERRED EMBODIMENT(S)

Methods of forming NMOS and PMOS transistors are presented, as are devices fabricated according to the methods of the present disclosure. One embodiment of the disclosure results in the growth of differential source/drains for NMOS or PMOS transistors. The disclosure further provides for embodiments whereby improved device performance can be achieved, through reduction of implantation defects and transient defect diffusion problems, by incorporating dopants into raised source/drain regions during epitaxial formation to produce sharper dopant profiles, as well as crystallographic lattice positions for the dopant that are better than positions resulting from conventional implantation schemes.

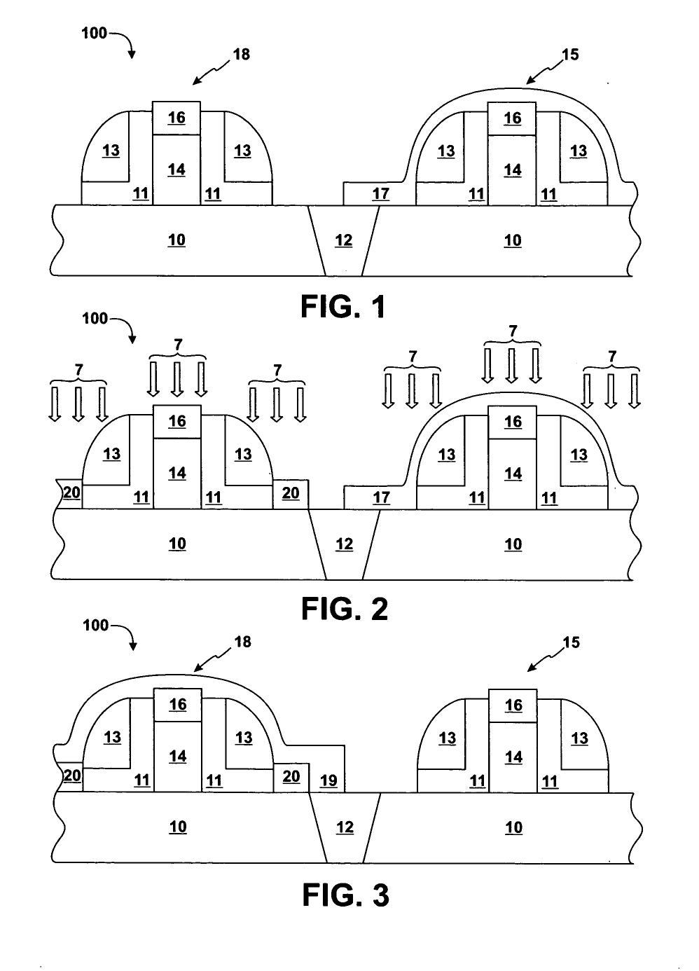

FIGS. 1 through 8 illustrate, in cross-section, a portion 100 of a semiconductor device during a manufacturing process according to an embodiment of the present disclosure. At the manufacturing stage presented in FIG. 1, gate structures 18 and 15 have been formed overlying a semiconductor substrate 10. The gate structure 18 is for an N-type transistor, and the gate structure 15 is for a P-type transistor, although the gate structures 18 and 15 can be described interchangeably such that the gate structure 18 is for a P-type transistor, and the gate structure 15 is for an N-type transistor.

In the example of FIG. 1, both gate structures 18 and 15 include conductive gate portions 14, liner oxide 11, spacers 13, and protective caps 16 overlying the conductive gate portions 14 of gate structures 15 and 18. Protective caps 16 can include antireflective coatings (ARC) or other materials such as silicon nitride or oxide. Other features of portion 100 include an isolation feature 12, and a protective layer 17.

Protective layer 17 has been formed overlying gate structure 15 and source/drain regions associated with gate structure 15. In an embodiment, protective layer 17 comprises a material selectively etchable with respect to a spacer material of the non-protected gate structures 18 and 19. The protective layer 17 will typically comprise an oxide or a nitride. The thickness of the protective layer 17 ranges from 100 to 1000 Angstroms. Thickness ultimately chosen should include consideration of the material's optical properties such that the selected thickness does not corrupt gate-patterning capabilities.

Semiconductor substrate 10 can be a silicon-on-insulator substrate. Alternatively, substrate 10 can also be a gallium arsenide substrate, a mono-crystalline silicon substrate, a silicon-on-sapphire substrate, or the like. Conductive gate structure portions 14 can be poly-crystalline or amorphous silicon having a length ranging from 200 to 1000 Angstroms or more, and a height ranging from 500 to 2000 Angstroms or more. The portion 100 is ready to undergo epitaxial formation, which can include selective epitaxial growth (SEG) and dopant incorporation, as illustrated in FIG. 2.

FIG. 2 illustrates portion 100 of FIG. 1 during formation of an epitaxial layer 20 over a source/drain region associated with the gate structure 18. During the epitaxial formation process, protective layer 17 prevents formation of an epitaxial layer over the S/D regions associated with gate structure 15. In an embodiment, the epitaxial layer 20 formed at the unprotected gate structure 18 S/D regions includes a dopant incorporation process 7 that can include an ion implantation process, a diffusion process, or an in situ process capable of incorporating the dopants in situ with growing the epitaxial layer to incorporate a first species of dopant. The dopant incorporation process 7 can utilize an n-type species of dopant, or a p-type species of dopant, depending upon the conductivity type requirements of a design. It should be noted that although it is not specifically illustrated, an epitaxial cap may be formed over the conductive gate structure 14 if protective layer 16 is removed prior to the epitaxial process, or if a protective layer 16 is not employed. The embodiment illustrated in FIGS. 2-7 illustrates no epitaxial cap formed over the unprotected gate structure 14.

In situ doping during epitaxial growth results in reducing the number of defects caused by ion implantation that occurs subsequent to epitaxial formation and the transient defect diffusion problems that can be caused by anneals that are used when regions are doped subsequent to epitaxial formation. Dopant incorporation 7 during epitaxial growth produces sharper dopant profiles, as well as producing crystallographic lattice positions for the dopant that are generally better than positions resulting from conventional implantation schemes.

Doping during epitaxial growth means results in dopants starting out on lattice sites during epitaxial formation, as opposed to doping schemes that require annealing to drive the dopants into the lattice. Defect rates produced as a result of performing dopant incorporation 7 during epitaxial growth have lower defect rates than when doping occurs after epitaxial growth.

In situ doping of the epitaxial layer 20 is accomplished by the addition of appropriate precursors into the process gases in the process tool, e.g., an LPCVD tool. Examples of suitable precursors are Diborane (B₂H₆), Arsine (AsH₃), Phosphine (PH₃), and others known in the art. The dopant profile created during the dopant incorporation 7 process can be a uniform dopant profile, or a gradient dopant profile, that is, a dopant profile with a gradient from one concentration of dopant to another concentration of dopant. A dopant gradient can be useful to optimize the connection to the transistor channel in some transistor architectures. In alternate embodiments diffusion techniques can be used to introduce doping into the epitaxial layer 20.

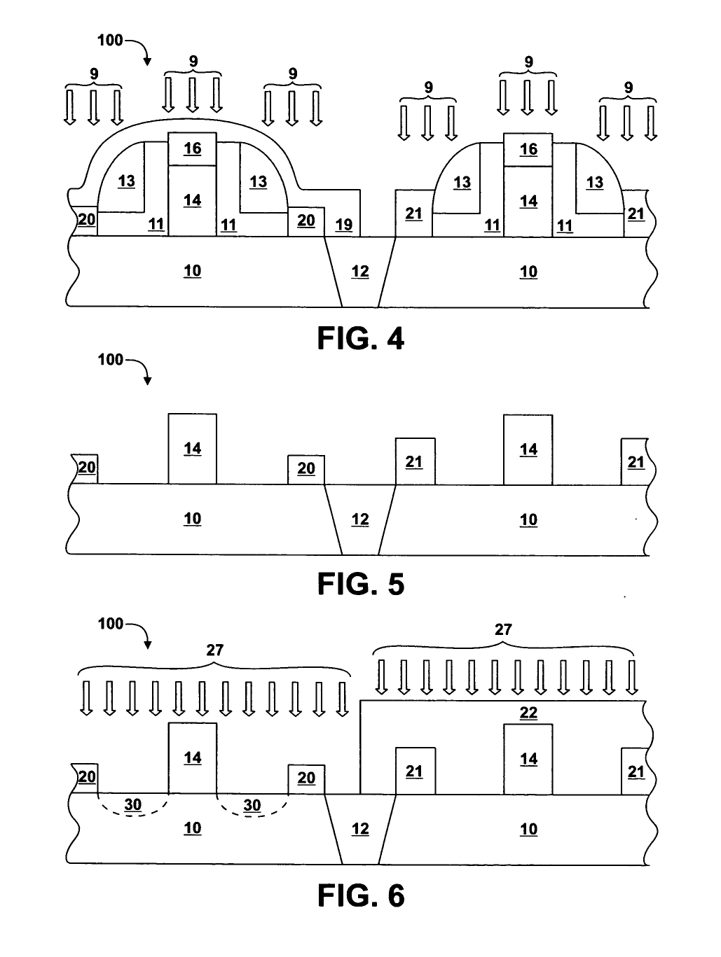

FIG. 3 shows portion 100 of FIG. 2 following the removal of protective layer 17 and the formation of a protective layer 19 overlying the gate structure 18 and source/drain region associated with the gate structure 18. Portion 100 is now ready to undergo raised S/D formation by performing another selective epitaxial growth and dopant incorporation process, as shown in FIG. 4.

Removal of the protective layer 17 is accomplished by methods suitable for the materials situation. It is desirable to have the protective layers comprised of a material which is the “opposite” of the material used in the spacer formation, e.g., a nitride protective layer with an oxide spacer, or an oxide layer with a nitride spacer. If protective layer 17 is an oxide, removal can be achieved using either a wet chemistry, e.g., hydrofluoric acid (HF), or a reactive ion etch (RIE) using, e.g., CH₄ or CH₃F. In the case of oxide spacers, a nitride hard mask is applied. The hard mask can be removed wet using phosphoric acid (H₃PO4) or dry (RIE), using CF₄/HBR or SF₆ or the like.

FIG. 4 illustrates portion 100 of FIG. 3 during epitaxial layer 21 growth. The formation includes dopant incorporation process 9 to form a doped epitaxial layer 21 overlying the now unprotected S/D region associated with gate structure 18. The protective layer 19 prevents formation of the epitaxial layer 21 overlying the gate structure 15. The dopant species utilized in creating the doped epitaxial layer 21 comprises a species of dopant different than the species utilized in the dopant (item 7, FIG. 2) during formation of the first epitaxial layer (item 17, FIG. 2). For example, if the earlier dopant incorporation process illustrated in FIG. 2 employed an n-type dopant, the dopant incorporation process 9 illustrated in FIG. 4 would utilize a p-type dopant.

The thickness of doped epitaxial layer 21 is illustrated to be different than the thickness of the doped epitaxial layer 20 of FIG. 2. Thus, the method of the present disclosure permits different source/drain thicknesses for respective NMOS or PMOS transistors. The differential thickness between source/drain regions of different conductivity types is achievable whether or not in situ doping of the epitaxial layers is used. In an embodiment, protective layer 19 comprises a material selectively etchable with respect to a spacer material of the gate structures 15 and 18. Typically, the protective layer 19 comprises a nitride or an oxide.

FIG. 5 illustrates portion 100 of FIG. 4 following complete removal of protective layer 19, spacers 13, gate oxide 11, and protective layer 16. Portion 100 is ready to undergo S/D extension manufacture, as illustrated in FIG. 6.

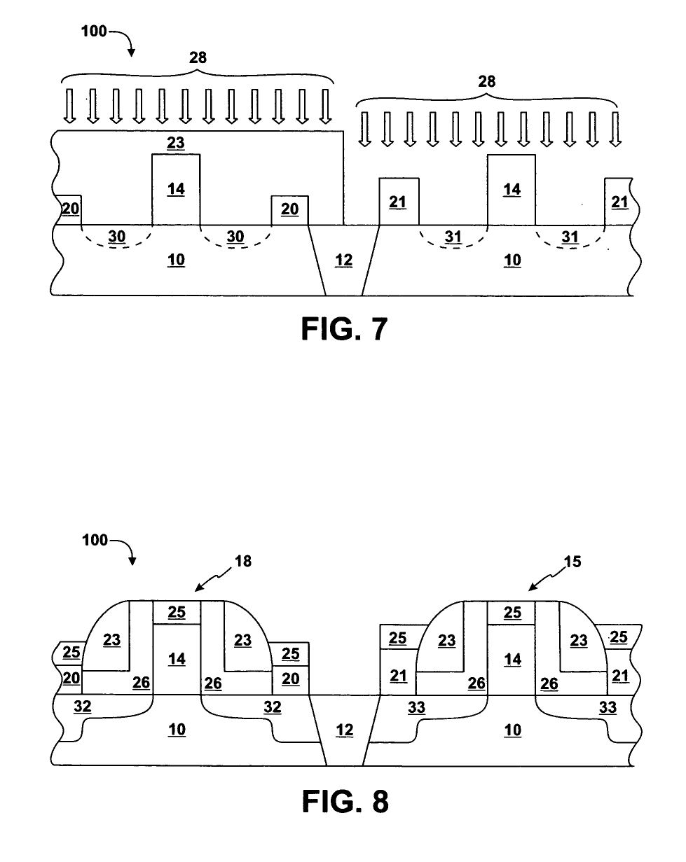

FIG. 6 illustrates portion 100 after conventional masking of the raised source/drains 21 and conductive gate portion 14 of one channel. The resist mask 22 protects that channel during implantation 27, which serves to create lightly doped drains (LDD) 30 and Halo implantations (not shown). The resist mask 22 is then stripped, and the process repeated for the other channel, as shown in FIG. 7.

FIG. 7 illustrates portion 100 after conventional masking of the raised source/drains 20 and conductive gate portion 14 of one channel. The resist mask 26 protects that channel during implantation 28, which serves to create lightly doped drains (LDD) 31 and Halo implantations (not shown) in the other channel. After extension formation processes, the resist mask will be stripped, and a rapid thermal anneal (RTA) performed to activate the dopants. Note that the conductivity types of the lightly doped drain regions and Halo implants are opposite for NMOS and PMOS transistors.

FIG. 8 illustrates portion 100 following the formation of a liner oxide 26, spacers 23 and a silicidation process to form a silicide 25 at conductive gate portions 14 and the epitaxial layers 20 and 21. By adjusting the heights of the epitaxial regions 20 and 21 independently, the distance of the silicide 25 from the channels of their respective NMOS and PMOS transistors can be controlled independently, and as needed, based on design requirements. For example, a thicker epitaxial layer, such as epitaxial layer 21 relative to SEG 20, will result in the silicide 25 associated with epitaxial layer 21 being further from a channel region under gate 14 than silicide 25 associated with epitaxial layer 21 is to its channel.

In addition, such as in the case of fully depleted epitaxial formation, consumption of the entire SEG layer can be undertaken to provide good contact to underlying plugs, such as tungsten plugs. Thus, the method disclosed herein provides the benefit of permitting differential heights based on the requirements of the transistor design criteria.

Spacers 23 will range in width, and can be differential, depending upon the amount of offset desired from the edge of the silicide layer 25 from the edges of conductive gate structures 14. Typical spacer widths are 50 to 1000 Angstroms. Source/drain regions 32 and 33 are also illustrated in FIG. 8 subsequent to formation of deep portions of the source/drain regions.

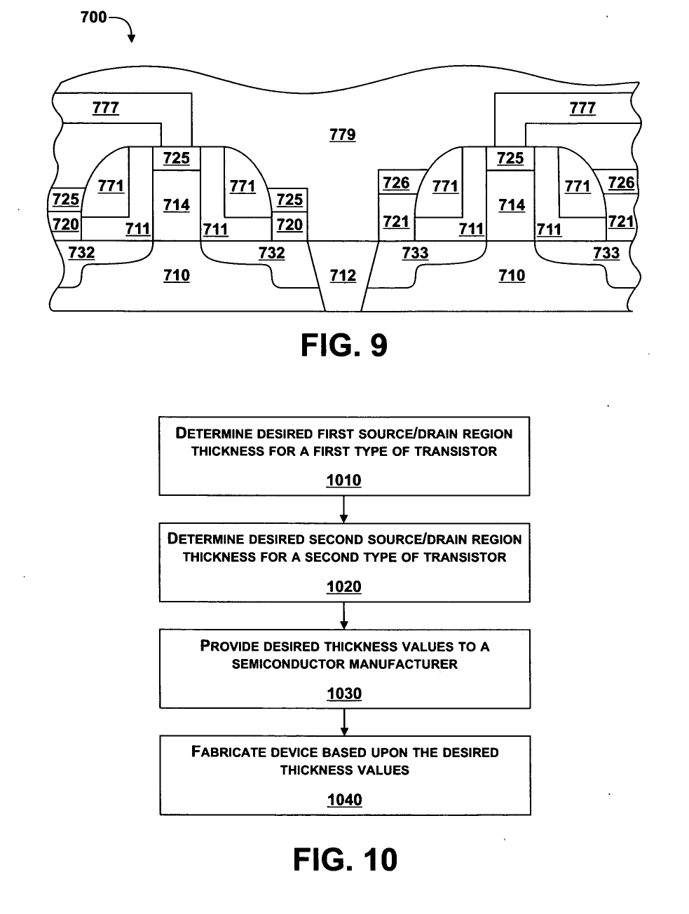

FIG. 9 illustrates, in cross-section, a portion 700 of a semiconductor device manufactured according to an embodiment of the present disclosure. FIG. 9 is a simplified diagram which does not necessarily show all of the features of portion 700 in order to keep the illustration from being cluttered.

The device of FIG. 9 comprises a structure 714 comprising an adjacent epitaxial layer 721 forming a raised source/drain of a first conductivity type and a first height. In addition, the device further comprises a gate structure 714 comprising an adjacent epitaxial layer 720 of a second conductivity type and a second height, where the second height is different than the first height. Depending upon transistor architecture or different diffusion behavior, the ability to produce differential heights in the combined SEG-silicide layers can be of benefit to the process engineer. In an embodiment, the epitaxial layer 721 adjacent the first gate structure 714 is of a first conductivity type, e.g., PMOS, and the second gate structure 714 is of a second conductivity type, e.g., NMOS.

Other features illustrated in FIG. 9 include interconnects 777 connected to vias/contacts (not numbered) within an interconnect dielectric region 779. The conductive gate structures 714 may include gate stacks comprising a dielectric layer (not shown) in addition to the doped epitaxial layers 720 and 721. In FIG. 9, deep source/drain regions 732, 733 in the substrate 710, along with silicided epitaxial layers 725, 726 are shown integrated with their respective transistors.

FIG. 10 is a flow diagram illustrating a method for determining a desired thickness of a source-drain region for a semiconductor device according to an embodiment of the present disclosure. At step 1010, a determination is made as to a desired thickness of a first source/drain (S/D) region for a first type of transistor. At step 1020, a determination is made as to a desired thickness of a second S/D region for a second type of transistor. These determinations are part of an integration scheme to consider a plurality of thicknesses and doped epitaxial growth processes at intervals integrated into a process line to produce a desired outcome. At step 1030, the desired thickness values are provided to a semiconductor device fabrication facility to implement the desired thickness. At step 1040, these values are utilized to fabricate devices based upon the desired thickness values. An example of such a device was illustrated in FIG. 9.

The method and apparatus herein provides for a flexible implementation. Although described using certain specific examples, it will be apparent to those skilled in the art that the examples are illustrative, and that many variations exist. For example, the disclosure is discussed herein primarily with regard to formation of for a CMOS device, however, the invention can be employed with other device technologies. Additionally, various types of deposition and etch devices are currently available which could be suitable for use in employing the method as taught herein. Note also, that although an embodiment of the present invention has been shown and described in detail herein, along with certain variants thereof, many other varied embodiments that incorporate the teachings of the invention may be easily constructed by those skilled in the art. For example, the technique is discussed primarily with regard to SOI substrates, though other substrates can be used. Also, the silicide described herein can be formed using a reactive process or a deposition process.

In addition, it will be appreciated that any number of substrate preclean steps can occur before the formation of any epitaxial layer. For example, U.S. patent application having Ser. No. 10/791,346, which is hereby incorporated in its entirety by reference, discloses several substrate preclean techniques appropriate for cleaning a substrate prior to forming an epitaxial layer.

In one example, contaminates on the surface of a substrate are subjected to a cleaning process comprising applying a plasma to a surface of the active regions produce a reduction reaction with the contaminates in an upper portion of the surface of the active regions. In an embodiment, the plasma comprises H₂. While the plasma is being applied to the upper portion of the exposed active regions, the resultant products or vapor byproducts of the reduction reaction are removed by the normal vacuum process within the chamber. Therefore, contaminates contained in the vapor byproducts and are vented away, leaving the upper portion of the surface of the active regions suitably clean for the ensuing epitaxial process. In one embodiment, the plasma process parameters comprise a gas flow of 450 sccm H2 and 300 sccm argon, at a chamber temperature of 400 degrees Celsius, with an high frequency (HF) power setting of 700 W, and a low frequency (LF) power setting of between approximately 50 to 100 W. Chamber pressure is 1 Torr, and the spacing between the surface of the active region and the faceplate of the tool (not shown) should be 300 mils. In other embodiments, plasma process parameters comprise a gas flow ranging from between 100-800 sccm H₂ and from between 100 and 600 sccm argon. Chamber temperatures can range between 300 to 450 degrees Celsius, and HF power settings from between 400-900 W, with LF power settings varying from between 0-150 W. Chamber pressures can range from between 1 mT-5 Torr, with spacing between the surface of the active region and the faceplate of the tool varying from between 200 to 400 mils. Exposure times for the various embodiments utilizing plasma range from between approximately 10 seconds up to approximately 120 seconds.

Various tool types are suitable for this cleaning, for example, CVD (Chemical Vapor Deposition) equipment, HDP (High Density Plasma) tools, etch chambers, or the like. Differences in chamber design, power settings, and species, e.g., H₂ with or H₂ without helium or nitrogen, will result in different thickness of the layer after anneal. Typically the layer after anneal will be between 20 and 50 Angstroms thick. This plasma cleaning process also results in passivation of Si—H bonds in the layer after anneal. No wet cleaning dip with hydrofluoric (HF) acid prior to SEG is necessary.

In addition to no longer requiring an HF dip prior to SEG, the reduced temperature of this H₂ plasma cleaning treatment results in a reduction of the SEG process thermal budget of more than 100 degrees Celsius. Typically pre-SEG cleaning processes are conducted at approximately 900 degrees Celsius or greater. In an embodiment of the present disclosure, the cleaning process occurs at less than approximately 800 degrees Celsius. In another embodiment, the cleaning process occurs at less than approximately 500 degrees Celsius or less. In addition, the cleaning processes of the present disclosure could be conducted at less than approximately 700 degrees Celsius or less, or even at less than approximately 600 degrees Celsius or less.

In another embodiment, location including includes a gate structure and active regions is subjected to a cleaning process utilizing a low-power dry etch to selectively remove an upper atomic layer of material from the active regions. The thickness of the upper atomic layer of material to be removed ranges from between 20 to about 50 Angstroms. In one embodiment, the dry etch process is an anisotropic dry etch utilizing a carbon-free gas as an etchant gas. In another embodiment, the anisotropic dry etch utilizes an oxygen- and carbon-free gas as an etchant gas. The etchant gas can comprise HBr, NF₃, SF₆, gaseous fluorine-interhalogenics such as ClF₃, or any gas containing fluorine, suitable to disassociate F-radicals, which does not contain oxygen and carbon. Prior to undergoing the anisotropic dry etch process, location 200 is subjected to a standard wet etch chemistry process utilizing a dilute HF solution (100:1) at room temperature, e.g., 20 to 26 degrees Celsius, for a time period ranging from 50 to 200 seconds. Following the HF clean, a low-power dry etch utilizing a temperature of approximately 400 degrees Celsius, RF power of approximately 375 W, pressure of approximately 150 mTorr, and a gas flow rate ranging from 50 to 100 sccm, is conducted. In other embodiments, the low-power dry etch utilizes a temperature ranging from between 300-500 degrees Celsius, with RF power ranging from between 200-700 W, a pressure ranging between 0-1 Torr, and a gas flow rate ranging from between 10-300 sccm, for a time ranging between 10 to 60 seconds.

This low-power dry etch removes carbon and oxygen contamination, and provides a very clean surface for SEG. The low temperature HF clean followed by the low-power dry etch does not require a high temperature bake. This results in a reduction of thermal budget for SEG of more than 100 degrees Celsius.

In another embodiment, a cleaning process is used that forms an oxidation layer of between 20 to 50 Angstroms on an upper surface of the active regions using a plasma to produce the oxidation layer on doped active regions. In an embodiment, the plasma is an O₂ plasma. In another embodiment, the plasma is an O₃ plasma.

An O₂ plasma production utilizes O₂ gas at a flow rate of 400 sccm, a pressure of 5 Torr, an HF of 300 W, an LF of 100 W, and a temperature of 400 degrees Celsius, with the time ranging from between about 10 to about 120 seconds. The spacing between the surface of the active regions and the faceplate of the vapor deposition apparatus (not shown) should be 400 mils. In other embodiments, the plasma production utilizes O₂ gas at a flow rate of between 100 and 1000 sccm, a pressure ranging from between 2-10 Torr, an HF ranging between 200-500 W, an LF ranging between 50-200 W, a temperature ranging between 300-450 degrees Celsius, for a time ranging from between approximately 10 to approximately 120 seconds. In an embodiment, the spacing between the surface of the active regions and the faceplate of the vapor deposition apparatus ranges from between 200 and 600 mils. The tool type used to generate the plasma could be CVD equipment, HDP tools, or etch chambers. In an embodiment where the plasma is O₃, plasma production utilizes O₃ gas at a flow rate of 300 sccm, a pressure of 5 Torr, an HF of 300 W, an LF of 100 W, and a temperature of 400 degrees Celsius for a time period ranging from between 10 to 120 seconds. The spacing between the surface of the active regions and the face plate of the vapor deposition apparatus (not shown) should be 400 mils. In other embodiments, plasma production utilizes O₃ gas at a flow rate of between 50 and 600 sccm, a pressure ranging from between 2-10 Torr, an HF ranging between 200-500 W, an LF ranging between 50-200 W, and a temperature ranging from between 300-450 degrees Celsius for a time period ranging from between about 10 to about 120 seconds. In an embodiment, the spacing between the surface of the active regions and the faceplate of the vapor deposition apparatus ranges from between 200 and 600 mils. As was the case with the O₂ plasma, the tool type used to generate the plasma could be HDP tools, CVD equipment, or etch chambers.

Forming the oxidation layer facilitates trapping or fixing contamination in the oxide layer overlying the upper layer of the doped active regions for subsequent removal using a wet chemistry process. The wet etch chemistry process utilizes a dilute HF acid solution of 100:1 at room temperature, e.g. 20 to 26 degrees Celsius, for a time ranging from 50 to 200 seconds. Differences in chamber design, power settings and species employed, e.g., O₂ or O₃, results in differing thickness of the oxidation layer, hence the wide range in times for the HF dip. The use of an O₂ or O₃ plasma to create a contamination-trapping oxidation layer for removal by a room temperature HF dip results in a reduction of the thermal input for location 300.

Another possible pre-clean for use prior to formation of an SEG is disclosed in U.S. patent application having Ser. No. 10/969,769, (Attorney Docket Number 1458-H1962) which is hereby incorporated in its entirety by reference, discloses another substrate preclean technique that facilitates a reduced temperature H₂ bake is performed following formation of any desired spacers, which can comprise one or more nitride or oxide layers and prior to SEG formation. This pre-clean and comprises a first pre-rinse with deionized water, followed by an oxide etch utilizing an aqueous solution of deionized water and hydrofluoric acid (HF or hydrogen fluoride in water) aqueous solution of approximately 30:1 (volumetric ratio) at 21 degrees Celsius, for a time period ranging from between 50-60 seconds. The weight percentage of HF recommended for the HF aqueous solution is 49% in a balance of deionized water (H₂O). Bulk HF aqueous solution can be purchased from various chemical suppliers in the HF weight percent range of 10% to 49%. In semiconductor fabrication facilities, this aqueous HF aqueous solution is typically diluted in the range 10:1 to 200:1. A 10:1 HF is 1 part aqueous HF (at 49% weight percent) and 10 parts H₂O. It will be appreciated that the etch rate of the HF aqueous solution is substantially linear with respect to both the concentration of the HF aqueous solution and the etch time. Therefore, various combinations of HF concentrations and etch times can be used to accomplish the oxide etch. Additionally, the temperature may vary.

After the HF etch, an overflow rinse utilizing deionized water is performed for a period ranging from approximately 120 to 600 seconds with a typical rinse being about 400 seconds. The cleaning process of portion 100 results in etching away of the surface contamination/debris located on substrate 10 resulting from offset spacer formation and/or dopant implantation. The upper semiconductor surface, i.e. silicon surface, of substrate 10 is also slightly etched, for example, from one to several mono layers of silicon, during the HF etch.

It should be noted that the amount of material removed during the HF etch is dependent upon the type of material being removed. For example, when native oxide is present, the HF etch will remove approximately 20 to 30 Angstroms of oxide. If a deposited oxide layer is present in addition to a native oxide, an over-etch of approximately 30% is generally desirable. For example, if removal of 100 Angstroms of a chemical vapor deposition (CVD) oxide is desired, the HF etch could be employed to remove approximately 120 to 130 Angstroms oxide removal. This latter example would be applicable in applications where a liner oxide of approximately 100 Angstroms thickness is employed between a conductive gate 25 and a nitride spacer.

The next steps in the cleaning process comprise a second pre-rinse with deionized water of approximately 30 seconds duration precedes the performance of a Standard Clean-1 (SC-1), a quick dry rinse (QDR), and a Standard Clean-2 (SC-2). The SC-1 and SC-2 components are followed by a second QDR, and an HF: H₂O etch, a third rinse, and an isopropyl alcohol (IPA) dry. The amount of material removed by the SC-1 and SC-2 components are implemented such that they etch from approximately one monolayer of silicon to approximately 10 to 100 Angstroms of silicon.

In an embodiment, the SC-1 utilizes an aqueous solution of ammonium hydroxide: hydrogen peroxide: deionized water at a ratio of approximately 1:1-4:6-40, at a temperature of approximately 60 degrees Celsius for approximately 72 minutes, to etch approximately 100 Angstroms of silicon. Synonyms for ammonium hydroxide (NH₄OH) include ammonia solution (typically contains between 12% and 44% ammonia before dilution), dilute ammonia, or concentrated ammonia. A first quick dry rinse is conducted for approximately 3 minutes. In an embodiment, the SC-2 utilizes a solution of hydrochloric acid: hydrogen peroxide: deionized water at an initial ratio of approximately 1:1:50 at a temperature of approximately 60 degrees for about 5 minutes. A second quick dry rinse is then conducted. Synonyms for hydrochloric acid (HCl) are hydrogen chloride, anhydrous hydrogen chloride, aqueous hydrogen chloride, chlorohydric acid, spirit of salts, and muriatic acid.

In a particular embodiment, the SC-1 utilizes a solution of ammonium hydroxide: hydrogen peroxide: deionized water at a ratio of approximately 1:4:20 at a temperature ranging of approximately 60 degrees Celsius for approximately 72 minutes. The SC-1 is the step in the clean sequence that etches the silicon. This occurs because the H₂O₂ (the oxidizer) becomes depleted in the solution with increasing time and increasing temperature. The methods of the present disclosure allow the initial concentration of hydrogen peroxide to be depleted to facilitate etching of the upper-most semiconductor portion. Depletion of the H₂O₂ is greatly enhanced when the solution temperature rises above 80 degrees Celsius, which can lead to an etch that is difficult to control if not carefully monitored. The temperature range of the SC-1 is expected to be approximately 55 to 85 degrees Celsius, with the etch occurring in a shorter period of time at higher temperatures than at lower temperatures. It is expected that the SC-1 etching will be better controlled at temperatures in the range of 55-80 degrees Celsius and better still at temperatures in the range of 55-75 degrees Celsius. Generally, it is expected that the substrate will be exposed to the SC-1 etch process for longer that 60 minutes. When the oxidizer stops protecting the silicon surface, the ammonium hydroxide (NH₄OH) starts to etch the silicon. Thus, a small amount of silicon can be etched in a controlled manner. The SC-1 can be performed in a re-usable bath where the solution is re-circulated and heated to maintain the desired temperature.

The mechanism of silicon and SiO₂ etching by a NH₄OH/H₂O₂ solution occurs when the solution is allowed to be depleted of H₂O₂. An alkaline solution, such as NH4OH4 in our example, will attack silicon by water molecules, according to the reaction:
Si+2H₂O+2OH⁻→Si(OH)₂(O⁻)₂+2H₂↑
A passivation layer formed by the H₂O₂ prevents this attack by the NH₄OH. H₂O₂ decomposes in the course to form O₂ and H₂O.
H₂O₂—→H₂O+½O₂
When the concentration of H₂O₂ is below 3×10⁻³M, then silicon will begin to etch, because of the absence of the inhibition layer.

As indicated in the above equations, heat is given off as the H₂O₂ is depleted. If a bath is used that is not recharged with fresh solution all H₂O₂ will be depleted, thereby no longer releasing heat. Therefore, the temperature can be monitored on the low end to indicate when the solution should be refreshed, while the temperature on the high end is monitored to prevent unusually rapid decomposition of the H₂O₂, which can lead to a process that is difficult to control.

The first quick dry rinse is conducted for approximately 3 minutes. The subsequent SC-2 utilizes a solution of hydrochloric acid: hydrogen peroxide: deionized water at a ratio of approximately 1:1:50 at a temperature of approximately 60 degrees for about 5 minutes. A quick dry rinse with deionized water, followed by an IPA dry process, is performed following the SC-2.

The IPA dry process uses a heated IPA vapor at approximately 82 degrees Celsius. The IPA vapor is generated in a separate chamber with 100% N₂ bubbled through 100% IPA (heated to 82 degrees Celsius). The IPA condenses on the wafer, and the solution drips off the bottom of the wafer. The IPA vapor concentration is slowly diluted to 100% N₂ before the wafers are removed from the rinsing/drying tank.

Subsequent to the SC-1 and SC-1 processes, the substrate will be further recessed (etched) as a result of the cleaning process. Next, an HF:H2O etch can be conducted at an aqueous solution ratio of 200:1 for about 65 seconds, which typically results in approximately 30 Angstroms of oxide removal. The HF:H2O etch 8 is followed by a rinse with deionized water for approximately 10 minutes duration. The deionized water rinse is followed by an IPA dry as described in the preceding paragraph. At this time, the source/drain regions of the substrate are ready for ion implantation or selective epitaxial growth.

In a particular embodiment, the SC-1 process comprises a pre-rinse with deionized water of approximately 30 seconds duration. The pre-rinse is followed by a SC-1 solution at a ratio of approximately 1:1-4:6-40, which includes the subranges of 0.25:1:5, 0.5:1:5, 1:1:5, 1:1:6, 1:4:20, and 1:1:40, ammonium hydroxide: hydrogen peroxide: deionized water at a temperature of approximately 60 degrees Celsius for approximately 5 minutes. A quick dry rinse (QDR) is then performed for approximately 3 minutes.

Following the SC-1 cleaning process, an SC-2 cleaning process is performed. In an embodiment, the SC-2 cleaning process includes utilizing an aqueous solution of hydrochloric acid: hydrogen peroxide: deionized water at a ratio of approximately 1:1:50 at a temperature of approximately 60 degrees Celsius for approximately 5 minutes. A QDR is then performed, and portion 200 is ready for the third cleaning. The weight percent composition of the hydrochloric acid: hydrogen peroxide: deionized water is 29% (weight percent) hydrochloric acid and 30% (weight percent) hydrogen peroxide in a balance of deionized water.

After the SC-1 and SC-2, a third cleaning process comprising an approximate 30 second pre-rinse, an oxide etch, an overflow rinse and an IP dry is performed. The oxide etch is accomplished utilizing a solution of deionized water and hydrofluoric acid at a ratio of approximately 200:1 for a time period ranging from between 450-650 seconds. Following the HF etch, an overflow rinse is performed for approximately 10 minutes. A final isopropyl alcohol (IPA) dry is then performed. Approximately 120-140 Angstroms of the surface of substrate is removed in this process. Portion 200 is ready to undergo selective epitaxial growth.

The above-described cleaning process has been found to facilitate formation of an epitaxial layer on a semiconductor surface, specifically silicon. Because various etch processes can etch N- and P-type regions at different rates, it can be useful to amorphize an upper-most surface of the source/drain regions prior to the above-described clean to reduce any preferential etch differences between substrate regions of differing dopant types.

For example, the above-described clean process can etch the N-type silicon preferentially, as compared to the P-type silicon, resulting in a quality difference of the SEG between the N and P regions after SEG processing. Etch rate differences between N- and P-type regions can allow for contaminates to remain in the lesser-etched region. For example, an etch process that does not etch P-type regions at the same rate as N-type regions can result in P-regions maintaining embedded carbon that is incorporated from previous process steps. Without appropriate etching of silicon in the P-type regions during the clean, the carbon will remain, and the SEG will grow inconsistently. A high bake temperature of 900° C. can be used to overcome this growth issue on P areas, however, as stated previously, high bake temperatures can be detrimental to the device in that it causes diffusion and deactivation of the dopants. Amorphizing the source/drain regions can reduce etch differences associated with the above-described cleaning process as well as other processes that are used to etch doped substrate regions, thereby improving the quality of both the N and P regions.

It has been observed that the selective etching may be P-type over N-type, or N-type over P-type depending on the solution temperature, flow rate of the aqueous ammonia, concentration of the aqueous ammonia, agitation, or illumination of light. By amorphizing the silicon in this manner to a pre-defined depth, it has been observed that unbiased etching to the depth of the amorphized silicon can be achieved.

In one embodiment, N- and P-type extensions formed in the source/drain regions are amorphized by being implanted with the Xe, at a dose of 2E14 and energy of 10 keV, to create an amorphous depth of 100A.

In accordance with another embodiment, a spacer structure having an undercut can be used to reduce or inhibit facet formation during a selective epitaxial growth process. Such a process can allow for greater lateral uniformity of junction or silicide features during implantation or silicidation processes, and can be accomplished by using a spacer formed with a bi-layer of materials, e.g., a thin liner, such as portion 29 of FIG. 1, of one material underlying another layer of material from which the ‘main’ spacer is formed. The thin liner and other material layer are selected such that the two materials are selectively etchable with respect to the other, for example, a thin oxide liner and a nitride layer. By etching the underlying portion of the spacer, an undercut can be formed that reduces facets during epitaxial formation.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present invention is not intended to be limited to the specific form set forth herein, but on the contrary, it is intended to cover such alternatives, modifications, and equivalents, as can be reasonably included within the spirit and scope of the invention.

What is claimed is:

1. A method comprising:
forming a first gate structure and a second gate structure overlying a semiconductor substrate;
forming a first protective layer overlying the first gate structure and a first source/drain region associated with the first gate structure; and
forming a first epitaxial layer overlying a second source/drain region associated with the second gate structure prior to removal of the first protective layer, wherein the first protective layer prevents formation of the first epitaxial layer at a first location.

2. The method of claim 1, wherein forming the first epitaxial layer overlying the second source/drain region further comprises incorporating a first dopant into the epitaxial layer during growth of the first epitaxial layer.

3. The method of claim 2, wherein the first dopant comprises a p-type dopant.

4. The method of claim 2, wherein the first dopant comprises an n-type dopant.

5. The method of claim 1, wherein the first protective layer comprises a material selectively etchable with respect to a spacer material of the first gate structure.

6. The method of claim 5, wherein the protective layer comprises an oxide.

7. The method of claim 5, wherein the protective layer comprises a nitride.

8. The method of claim 1, wherein the first gate structure is for an N-type transistor, and the second gate structure is for a P-type transistor.

9. The method of claim 1, wherein the first gate structure is for a P-type transistor, and the second gate structure is for an N-type transistor.

10. The method of claim 1, wherein forming the first gate structure and the second gate structure further comprises forming an epitaxial cap over the second gate structure.

11. The method of claim 1, wherein forming the first gate structure and the second gate structure further comprises not forming an epitaxial cap over the second gate structure.

12. The method of claim 1, further comprising:
removing the first protective layer overlying the first gate structure and the first source/drain region;
forming a second protective layer overlying the second gate structure and a second source/drain region associated with the second gate structure; and
forming a second epitaxial layer overlying a first source/drain region associated with the first gate structure, wherein the second protective layer prevents formation of the second epitaxial layer overlying the second gate structure.

13. The method of claim 12, further comprising:
forming the second epitaxial layer further comprises the second epitaxial layer overlying the second source/drain region further comprises incorporating a second dopant into the epitaxial layer during growth of the first epitaxial layer.

14. The method of claim 12, wherein a thickness of the second epitaxial layer is substantially different than a thickness of the first epitaxial layer.

15. The method of claim 12, wherein the second protective layer comprises a material selectively etchable with respect to a spacer material of the second gate structure.

16. The method of claim 15, wherein the second protective layer comprises a nitride.

17. The method of claim 15, wherein the second protective layer comprises an oxide.

18. A method of forming a semiconductor device, the method comprising:
determining a first source drain thickness for a transistor of a first type;
determining a second source drain thickness for a transistor of a second type;
providing the desired thickness values to a semiconductor device fabrication facility; and
fabricating a device based upon the desired thickness values.

19. A device comprising:
a first gate structure comprising a first source/drain of a first conductivity type and a first height, the first source/drain comprising a raised epitaxial layer; and
a second gate structure comprising a second source/drain of a second conductivity type and a second height, the second source/drain comprising a raised epitaxial layer, wherein the second height is substantially different than the first height.

20. The device of claim 18, wherein the epitaxial layer adjacent the first gate structure is of a first conductivity type and the second gate structure is of a second conductivity type.
